(19) United States
(12) Patent Application Publication
(10) Pub. No.: US 2024/0425985 A1
(43) Pub. Date: Dec. 26, 2024

(54) METHODS AND SYSTEMS FOR PRECURSOR LEVEL MONITORING

(71) Applicant: ASM IP Holding B.V., Almere (NL)

(72) Inventors: Antti Niskanen, Helsinki (FI); Vincent Vandalon, Heverlee (BE)

(21) Appl. No.: 18/747,162

(22) Filed: Jun. 18, 2024

Related U.S. Application Data
(60) Provisional application No. 63/510,293, filed on Jun. 26, 2023.

(51) Int. Cl. C23C 16/455; C23C 16/52

(52) U.S. Cl. CPC C23C 16/45544; C23C 16/45553; C23C 16/52

(57) ABSTRACT

Methods and related systems, precursor vessels, data processing systems, computer program products, and computer-readable media that can be employed for determining an amount of precursor in a precursor vessel. Embodiments of presently described methods can comprise carrying out an analyzing sequence, by a processor, of at least the pressure as a function of time, thereby quantifying a remaining amount of the precursor.

### CROSS-REFERENCE TO RELATED APPLICATION(S)

This application claims the benefit of U.S. Provisional Application 63/510,293 filed on Jun. 26, 2023, the entire contents of which are incorporated herein by reference.

### FIELD OF INVENTION

The present disclosure is in the field of integrated device manufacture, in particular in the field of vapor deposition tools, systems, and processes for integrated circuit manufacture, and more particularly technology for determining the amount of precursor, e.g. solid precursor, in a precursor vessel for a semiconductor manufacturing process.

### BACKGROUND OF THE DISCLOSURE

With semiconductors and semiconductor manufacturing processes becoming more advanced, there is a need for greater uniformity and process control during the manufacturing process.

During processes such as Atomic Layer Deposition (ALD), Epitaxy and Chemical Vapor Deposition (CVD) precursors which may be in the form of a gas, liquid or solid are deposited onto or contacted with a workpiece. These precursors are often stored in precursor container or precursor vessel from where they are transported to the workpiece in the reaction chamber.

While the process is being performed, it may be advantageous to monitor the amount of precursor in the precursor vessel in order to prevent manufacturing defects due to exhaustion of the precursor material. The ability to monitor remaining amount of precursor material in the precursor vessel is important because it ensures process quality, allows efficient scheduling of precursor vessel changes, maximizes use of expensive chemistry, and improves inventory management.

Whereas level sensing is industry standard for gaseous or liquid materials, monitoring the remaining amount of a solid precursor material is more complex. Typically, the precursor material is transported from the precursor vessel to the reactor chamber by flowing a carrier gas through the precursor vessel, thereby generating a process gas comprising the carrier gas and vaporized solid precursor which is subsequently provided to the process chamber. Several of the process conditions employed to the manufacturing process (e.g. high temperature range, the use of carrier gas . . . ) result in the monitoring of the precursor level becoming challenging for existing level sensing systems especially when resolution and accuracy are key.

Therefore, a need exists for an improved method and apparatus for monitoring the amount of solid precursor in a precursor vessel for a semiconductor manufacturing process.

### SUMMARY OF THE DISCLOSURE

Described herein is a method comprising providing a plurality of precursor pulses from a precursor vessel to a precursor line in fluid connection with the precursor vessel. The precursor vessel can comprise a precursor. The method can comprise sensing, by means of a pressure gauge, a pressure as a function of time comprising a plurality of pressure pulses. The method can further comprise carrying out an analyzing sequence, by means of a processor, of at least the pressure as a function of time, thereby quantifying a remaining amount of the precursor. The method can further comprise comparing the remaining amount of the precursor to a pre-determined precursor amount. If the remaining amount of the precursor exceeds the pre-determined precursor amount, a sufficient precursor signal can be generated. If the remaining amount of the precursor is at most equal to the pre-determined precursor amount, an insufficient precursor signal can be generated.

Further described herein is a system that comprises a precursor vessel connector constructed and arranged for operationally connecting to a precursor vessel comprising a precursor, e.g. a solid precursor. The reaction chamber can be in fluid connection with the precursor vessel via a precursor line. The reaction chamber can be constructed and arranged for receiving a plurality of precursor pulses from the precursor vessel via the precursor line. The system can further comprise a pressure gauge that is constructed and arranged for sensing a pressure as a function of time. The pressure as a function of time can comprise a plurality of pressure pulses. The system can further comprise processer. The processor can be constructed and arranged for carrying out an analyzing sequence that comprises analyzing at least the pressure as a function of time, thereby quantifying a remaining amount of the precursor; comparing the remaining amount of the precursor to a pre-determined precursor amount; and, comparing the remaining amount of the precursor to a pre-determined precursor amount. If the remaining amount of the precursor exceeds the pre-determined precursor amount, the processor can generate a sufficient precursor signal. If the remaining amount of the precursor is at most equal to the pre-determined precursor amount, the processor can generate an insufficient precursor signal.

In some embodiments, the precursor is in a solid state.

In some embodiments, the precursor comprises a metal center and one or more ligands.

In some embodiments, the ones from the plurality of pulses comprise at least one of an attack portion, a sustain portion, and a decay portion. The remaining amount of the precursor can be determined by analyzing one or more of the attack portion, the sustain portion, and the decay portion.

In some embodiments, the attack portion comprises a linear segment. In such embodiments, the remaining amount of the precursor can be quantified as being critically low.

In some embodiments, the pressure gauge is positioned in the precursor vessel.

In some embodiments, the attack portion comprises a saturating segment, and the remaining amount of the precursor is quantified as being sufficient. In some embodiments, a saturating segment of an attack portion can be considered to be, or modelled as, a sustain portion.

In some embodiments, if the sufficient precursor signal is generated, a cyclical deposition process can be executed using the precursor in a reaction chamber which is in fluid connection with the precursor vessel via the precursor line.

In some embodiments, if the insufficient precursor signal is generated, the insufficient precursor signal prevents the system from executing a cyclical deposition process using the precursor in a reaction chamber which is in fluid connection with the precursor vessel via the precursor line.

In some embodiments, the remaining amount of the precursor is determined by analyzing the attack portion. Analyzing the attack portion can comprise fitting the attack portion using a function selected from an exponential function, a four parameter logistic function, and an Arrhenius function.

In some embodiments, the exponential function is a three-parameter exponential function of the form P(t)=A−B*exp(−Ct). A, B, and C can be positive real numbers.

In some embodiments, the precursor vessel further comprises a capacitive sensor that is constructed. The precursor vessel can be arranged for measuring a sensed capacitance. The analyzing sequence can comprise determining the remaining amount of the precursor based on the sensed capacitance in addition to the pressure as a function of time.

In some embodiments, the analyzing sequence comprises determining, based on the sensed capacitance, a capacitance-derived remaining amount of the precursor; determining, based on the pressure as a function of time, a pressure-derived remaining amount of the precursor; comparing the capacitance-derived remaining amount of the precursor and the pressure-derived remaining amount of the precursor; and, if the capacitance-derived remaining amount of the precursor and the pressure-derived remaining amount of the precursor are equal within a pre-determined margin of error, quantifying the remaining amount of the precursor comprises setting the remaining amount of the precursor equal to the capacitance-derived remaining amount of the precursor, to the pressure-derived remaining amount of the precursor, or to an interpolated value thereof; else, generating an error signal.

Further described herein is a precursor vessel that comprises a precursor, a pressure gauge, and a capacitive sensor. The precursor vessel can be fluidly connectable to a reaction chamber via a precursor line. The reaction chamber and the precursor line can be comprised in a vapor deposition system. The reaction chamber can be constructed and arranged for receiving a plurality of precursor pulses from the precursor vessel via the precursor line. The pressure gauge can be constructed and arranged for sensing a pressure as a function of time, the pressure as a function of time comprising a plurality of pressure pulses. The capacitive sensor can be constructed and arranged for measuring a sensed capacitance. The precursor vessel can be operationally connectable to a processer comprised in the vapor deposition system, the processer being constructed and arranged for carrying out an analyzing sequence that comprises analyzing one or both of the pressure as a function of time and the sensed capacitance, thereby quantifying a remaining amount of the precursor; comparing the remaining amount of the precursor to a pre-determined precursor amount; and, if the remaining amount of the precursor exceeds the pre-determined precursor amount, generating a sufficient precursor signal; and, if the remaining amount of the precursor is at most equal to the pre-determined precursor amount, generating an insufficient precursor signal.

In some embodiments, the precursor comprises a solid precursor.

In some embodiments, the precursor comprises a center and one or more ligands, wherein the center is selected from a transition metal, a post transition metal, a lanthanide, and a metalloid; and wherein the one or more ligands are independently selected from the list consisting of arene, halide, alkyl, cyclopentadienyl, amide, chelating nitrogen-containing ligand, alkoxide, beta-diketonate, and carbonyl.

Further described herein is a data processing unit comprising a receiving unit constructed and arranged for receiving a pressure as a function of time, the pressure as a function of time comprising a plurality of pressure pulses; an analyzing unit constructed and arranged for carrying out an analyzing sequence of at least the pressure as a function of time, thereby quantifying a remaining amount of a precursor; and, a comparison unit constructed and arranged for comparing the remaining amount of the precursor to a pre-determined precursor amount; and, a generating unit, the generating unit constructed and arranged for generating a sufficient precursor signal if the remaining amount of the precursor exceeds the pre-determined precursor amount; and, the generating unit being further constructed and arranged for generating an insufficient precursor signal if the remaining amount of the precursor is at most equal to the pre-determined precursor amount.

Further described herein is a computer program product comprising instructions to cause the data processing unit as described herein to execute the steps of a method as described herein.

Further described herein is a computer-readable medium having stored thereon a computer program product as described herein.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 shows an embodiment of a processing system 100.

FIGS. 2A and 2B show embodiments of sub-systems 200.

FIG. 3 shows an example of a pressure evolution as a function of time for a full vessel.

FIGS. 4A, 4B, and 4C show stylized pressure versus time curves 400 of embodiments of precursor pulses.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). A pulse can comprise exposing a substrate to a precursor or reactant. This can be done, for example, by introducing a precursor or reactant to a reaction chamber in which the substrate is present. Additionally or alternatively, exposing the substrate to a precursor can comprise moving the substrate to a location in a substrate processing system in which the reactant or precursor is present.

Generally, for ALD processes, during each cycle, a precursor is introduced into a reaction chamber and is chemisorbed onto a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gasses that react with each other. For example, a purge, e.g. using a noble gas, may be provided between a precursor pulse and a reactant pulse, thus avoiding or at least minimizing gas phase interactions between the precursor and the reactant. In some embodiments, a “purge” may refer to a procedure in which a reactive purge gas is provided to a reaction chamber in between two pulses of gasses that react with each other, and that react with the purge gas.

It shall be understood that purges and pulses can be effected either in time or in space, or both. For example, in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied. For example, in the case of temporal pulses, a precursor can be provided for a pre-determined amount of time before and after which an inert gas is provided to the reaction chamber. For example, in the case of spatial pulses, a substrate can be moved through a pre-determined location at which precursor is provided and which is surrounded by one or more inert purge gas curtains.

As used herein, a “precursor” includes a gas or a material that can become gaseous and that can be represented by a chemical formula that includes an element which may be incorporated during a deposition process as described herein.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

Described herein are methods, systems, computer program products, precursor vessels, and computer-readable media that allow determining an amount of precursor that is comprised in a precursor vessel while it is in use. Such information can be highly advantageous in order to prevent precursor depletion-related misprocessing.

In some embodiments of a method as described herein, a plurality of precursor pulses are provided from a precursor vessel to a precursor line that is in fluid connection with the precursor vessel. The precursor vessel can be completely full, or it can be partially empty. In other words, the precursor vessel comprises a precursor. For example, the precursor vessel can be filled with a precursor for 100%, for 90%, for 80%, for 80%, for 70%, for 60%, for 50%, for 40%, for 30%, for 20%, for 10%, or for 5%. It shall be understood that these percentages can be suitably expressed as mass percentages, i.e. as “mass of the amount of precursor remaining in the precursor vessel” divided by the “mass of the precursor in the precursor vessel when the precursor vessel is full”.

During normal operation of a pulsed deposition process such as an atomic layer deposition process, valves can be sequentially operated to provide precursor from the precursor vessel to a reaction chamber in a plurality of pulses. For example, the following sequence comprising two alternating steps a) and b) can be used, e.g. for a solid precursor: a) vessel valve closed, no precursor is provided from the precursor vessel, and as the precursor sublimates, the precursor in the vessel rises asymptotically to the precursor's vapor pressure; b) vessel valves open, precursor is provided from the precursor vessel, pressure in the precursor vessel decreases. The inventors surprisingly discovered that at least one of the resulting pressure increases and pressure decreases can be used to characterize the amount of remaining precursor in the precursor vessel.

Thus, embodiments of presently described methods can comprise sensing, by means of a pressure gauge, a pressure as a function of time comprising a plurality of pressure pulses. In some embodiments, these pressure increases can be measured by a pressure gauge positioned in the precursor vessel. In some embodiments, the pressure decreases can be measured by a pressure gauge positioned in the precursor vessel, or by a pressure gauge positioned in a precursor line downstream from the precursor vessel and upstream from the reaction chamber.

Embodiments of presently described methods can comprise carrying out an analyzing sequence, by means of a processor, of at least the pressure as a function of time. Thus, the remaining amount of the precursor can be quantified.

Embodiments of presently described methods can comprise comparing the remaining amount of the precursor to a pre-determined precursor amount. If the remaining amount of the precursor exceeds the pre-determined precursor amount, a sufficient precursor signal can be generated. On the other hand, if the remaining amount of the precursor is at most equal to the pre-determined precursor amount, an insufficient precursor signal can be generated. In some embodiments, a sufficient precursor signal can cause a vapor deposition process employing the precursor to be carried out. In some embodiments, an insufficient precursor signal can cause a vapor deposition process employing the precursor to be prevented from being carried out.

In some embodiments, a method as disclosed herein can comprise a obtaining a first pre-determined precursor amount at a first time, and obtaining a second pre-determined precursor amount at a second time. In such embodiments, a rate of precursor consumption can be obtained from the first pre-determined precursor amount, the second pre-determined precursor amount, the first time, and the second time. In some embodiments, the rate of precursor consumption equals a precursor delta divided by a time delta, wherein the precursor delta equals the second pre-determined precursor amount minus the first pre-determined precursor amount, and wherein the time delta equals the second time minus the first time.

In some embodiments, a method as described herein can comprise generating an excess precursor consumption signal when the rate of precursor consumption exceeds a pre-determined precursor amount. When an excess precursor consumption signal is generated, a deposition process employing the precursor in question can be automatically terminated, e.g. by stopping precursor flow.

In some embodiments, the pressure measurements can be employed for deriving a dose during a pulse, e.g. during a single pulse. Dose can refer to the total amount of precursor that is extracted from a precursor vessel during a single pulse. In some embodiments, dose can be measured using a pressure gauge positioned inside the precursor vessel. In some embodiments, the precursor vessel is closed, i.e. its inlet and outlet valves are closed, between two subsequent pulses, a previous pulse and a next pulse. In such embodiments, dose can be determined by means of a pressure measurement just after the previous pulse, and a pressure measurement just before the next pulse. The amount of additional molecules in the gas phase just before the next pulse compared to just after the previous pulse equals the dose. This amount can be readily derived using a gas law, such as the ideal gas law or the real gas law (Van der Waals).

In some embodiments, a precursor vessel as described herein comprises a precursor in a solid form, i.e. a solid precursor.

Dose is seen just moments before the vessel inlet and/or outlet valves are opened. It's derived from the increase taking place during when the valves are closed, and the vessel isolated.

Further described herein is a system. The system can, in some embodiments, be constructed and arranged for carrying out a cyclic vapor phase deposition method such as atomic layer deposition. In some embodiments, the system is constructed and arranged for carrying out a method as described herein.

The system as described herein can comprise a precursor vessel connector that is constructed and arranged for operationally connecting to a precursor vessel. The precursor vessel comprises a precursor. In some embodiments, the precursor vessel is comprised in the system.

The system can further comprise a reaction chamber in fluid connection with the precursor vessel via a precursor line. The reaction chamber can be constructed and arranged for receiving a plurality of precursor pulses from the precursor vessel via the precursor line.

The system can further comprise a pressure gauge that is constructed and arranged for sensing a pressure as a function of time. The pressure as a function of time can comprise a plurality of pressure pulses.

The system can further comprise a processer. The processer can be constructed and arranged for carrying out an analyzing sequence that comprises analyzing at least the pressure as a function of time, thereby quantifying the remaining amount of the precursor. The analyzing sequence can further comprise comparing the remaining amount of the precursor to a pre-determined precursor amount. The analyzing sequence can further comprise comparing the remaining amount of the precursor to a pre-determined precursor amount. If the remaining amount of the precursor exceeds the pre-determined precursor amount, the processer can generate a sufficient precursor signal. If the remaining amount of the precursor is at most equal to the pre-determined precursor amount, the processer can generate an insufficient precursor signal.

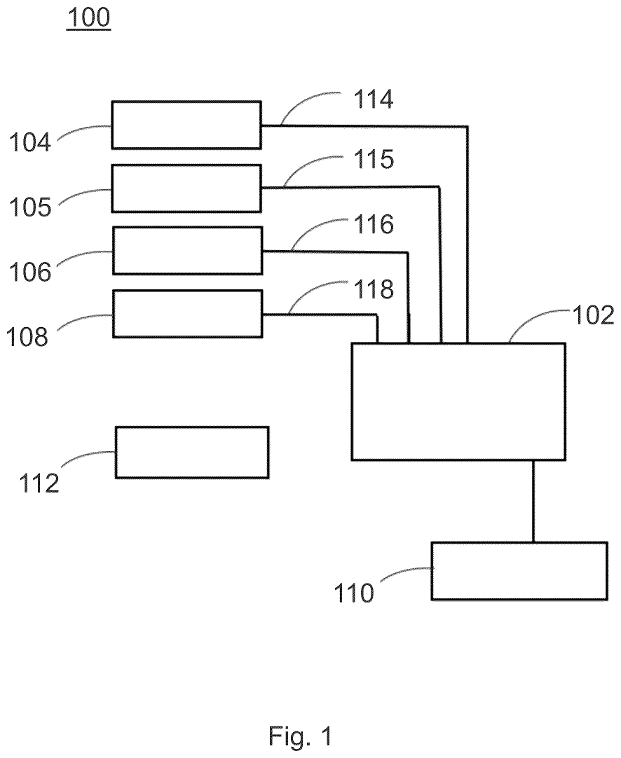

FIG. 1 shows an embodiment of a processing system 100 comprising one or more process chambers 102, a precursor gas source 104, a gas source 105, a reactant gas source 106, a purge gas source 108, an exhaust 110, and a process control unit 112.

The process chamber 102 can include any suitable process chamber, such as an atomic layer deposition (ALD) or chemical vapor deposition (CVD) reaction chamber.

The precursor gas source 104 can include a precursor vessel and one or more precursors as described herein-alone or mixed with one or more carrier (e.g. noble) gases. Suitably, at least one precursor vessel comprises a capacitive sensor system as described herein.

The reactant gas source 106 can include a vessel and one or more reactants as described herein-alone or mixed with one or more carrier gases. The purge gas source 108 can include one or more noble gases such as He, Ne, Ar, Kr, and/or Xe. Although illustrated with four gas sources 104-108, the system 100 can include any suitable number of gas sources. The gas sources 104-108 can be coupled to process chamber 102 via lines 114-118, which can each include flow controllers, valves, heaters, and the like. At least one of the gas sources comprises at least on of a pressure-based and a capacitance-based precursor level sensing mechanism as disclosed herein.

The exhaust 110 can include one or more vacuum pumps.

The process control unit 112 includes electronic circuitry and software to selectively operate valves, manifolds, heaters, pumps and other components included in the system 100. Such circuitry and components operate to introduce precursors and purge gases from the respective sources 104-108. The process control unit 112 can control timing of gas pulse sequences, temperature of the substrate and/or process chamber, pressure within the process chamber, and various other operations to provide proper operation of the system 100. The process control unit 112 can include control software to electrically or pneumatically control valves to control flow of precursors, reactants and purge gases into and out of the process chamber 102. The process control unit 112 can include modules such as a software or hardware component, e.g., a FPGA or ASIC, which performs certain tasks. A module can advantageously be configured to reside on the addressable storage medium of the control system and be configured to execute one or more processes.

Other configurations of the system 100 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the process chamber 202. Further, as a schematic representation of a system, many components have been omitted for simplicity of illustration, and such components may include, for example, various valves, manifolds, purifiers, heaters, containers, vents, and/or bypasses.

During operation of the reactor system 100, substrates, such as semiconductor wafers (not illustrated) are transferred from, e.g., a substrate handling system to the process chamber 102. Once substrates are transferred to the process chamber 102, one or more gases from the gas sources 104-108, such as precursors, reactants, carrier gases, and/or purge gases, are introduced into the process chamber 102.

Further described herein is a precursor vessel that comprises a precursor, a pressure gauge, and a capacitive sensor. The precursor vessel can be fluidly connected to, or connectable to, a reaction chamber via a precursor line. The reaction chamber and the precursor line can be comprised in a vapor deposition system. The reaction chamber can be constructed and arranged for receiving a plurality of precursor pulses from the precursor vessel via the precursor line. The pressure gauge can be constructed and arranged for sensing a pressure as a function of time. The pressure as a function of time can comprise a plurality of pressure pulses. The capacitive sensor being constructed and arranged for measuring a sensed capacitance. The sensed capacitance can be indicative of the remaining amount of precursor. Furthermore, the precursor vessel can be operationally connectable to a processer that is comprised in the vapor deposition system. The processer can be constructed and arranged for carrying out an analyzing sequence that comprises analyzing one or both of the pressure as a function of time and the sensed capacitance. Thus, a remaining amount of precursor can be quantified. The processer can be further constructed and arranged for comparing the remaining amount of the precursor to a pre-determined precursor amount. The processer can be further constructed and arranged for generating a sufficient precursor signal if the remaining amount of the precursor exceeds the pre-determined precursor amount. The processer can be further constructed and arranged for generating an insufficient precursor signal if the remaining amount of the precursor is at most equal to the pre-determined precursor amount.

Further described herein is a data processing unit. A data processing unit can, in some embodiments, comprise a processer. The data processing unit can comprise a receiving unit that is constructed and arranged for receiving a pressure as a function of time. The pressure as a function of time comprises a plurality of pressure pulses. The data processing unit can further comprise an analyzing unit. The analyzing unit can be constructed and arranged for carrying out an analyzing sequence of at least the pressure as a function of time. Thus, a remaining amount of the precursor can be quantified. The analyzing unit further comprises a comparison unit that is constructed and arranged for comparing the remaining amount of the precursor to a pre-determined precursor amount. The analyzing unit further comprises a generating unit. The generating unit can be constructed and arranged for generating a sufficient precursor signal if the remaining amount of the precursor exceeds the pre-determined precursor amount. The generating unit can further be constructed and arranged for generating an insufficient precursor signal if the remaining amount of the precursor is at most equal to the pre-determined precursor amount.

Further described herein is a computer program product that comprises instructions to cause the data processing unit as described herein to execute the steps of a method according to embodiments of the present disclosure.

Further described herein is a computer-readable medium having stored thereon the computer program product according to the present disclosure.

In some embodiments according to the present disclosure, the precursor can be in a solid state. In other words, and in some embodiments, the precursor is, substantially consists of, or can comprise, a solid precursor.

In some embodiments, the precursor comprises a precursor center and one or more ligands. The precursor center can, for example, comprise a metal center, or a metalloid center. Examples of metal centers include transition metal centers, alkaline metal centers, alkaline earth metal centers, post transition metal centers, and rare earth metal centers. Suitable metal centers include aluminum, indium, and tin. Suitable metalloid centers include silicon and germanium. Suitable rare earth metal centers include lanthanides such as lanthanum.

In some embodiments, the one or more ligands are independently selected from the list consisting of arene, halide, alkyl, cyclopentadienyl, amide, chelating nitrogen-containing ligand, alkoxide, beta-diketonate, and carbonyl. For example, suitable metal bis arenes include M(Bz)₂ and M(RBz)₂ with M being a transition metal, Bz being a benzene ring, and R being a C1 to C3 alkyl substituent on the benzene ring, for example Ru(Cp)₂ in which Cp is cyclopentadienyl. Suitable transition metals include tungsten, molybdenum, and ruthenium. Suitable transition metal halides include MoCl₅ and HfCl₄. For example, suitable transition metal beta diketonates include W(thd)3 in which thd stands for 2,2,6,6-tetramethyl-3,5-heptanedione.

Suitable precursors are described, for example, in “Barry, Sein Thomas, Peter George Gordon, and Vincent Vandalon. “Common Precursors and Surface Mechanisms for Atomic Layer Deposition.” Reference Module in Chemistry, Molecular Sciences and Chemical Engineering. Elsevier, 2022.”, which is incorporated by reference in its entirety.

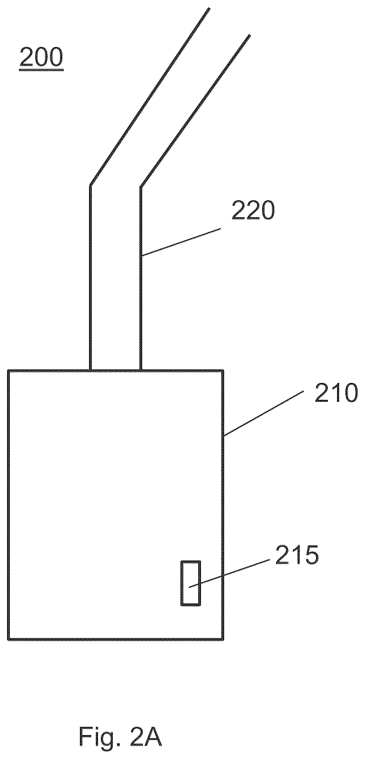

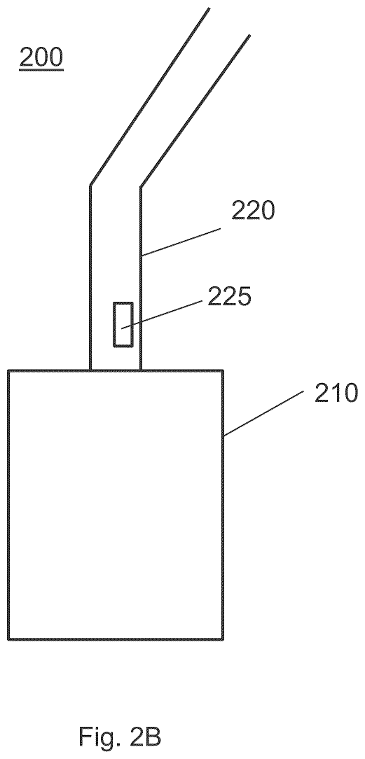

Further reference is made to FIGS. 2A and 2B, which show embodiments of sub-systems 200 comprising a precursor vessel 210, a precursor line 220, and a pressure gauge 215,225. In the embodiment of FIG. 2A, the pressure gauge 215 is installed in the precursor vessel 210. In the embodiment of FIG. 2B, the pressure gauge 225 is installed in the precursor line 220.

Now referring to the embodiment of FIG. 2A, in some embodiments of the present disclosure, the pressure gauge 215 is comprised in the precursor vessel 210. The pressure gauge 215 can monitor the vessel pressure increase characteristics when the precursor vessel 210 is isolated from the rest of the system in which the pressure vessel 210 is embedded. In particular, during a single ALD cycle, the precursor vessel can be open only for a short time—most of the time during the cycles, all the vessel valves (not shown) can be closed. When the vessel valves are closed, precursor vapor is generated inside the vessel, and the pressure in the vessel gradually increases. The rate and overall shape of this pressure increase can, in embodiments of the present disclosure, be used for characterizing the remaining amount of the precursor.

In particular, the vapor generation and the subsequent pressure increase (rate and non-linearity) can depend on the amount of precursor available in the vessel. When the vessel is empty there is no pressure increase from the precursor vapor generation. At a near-empty condition the pressure increase can be seemingly linear. When the vessel is full, the pressure increase curve can be a saturating one, with an initial linear region followed by slow, gradual slowing of the increase caused by vapor pressure reaching saturation. This behavior can be modeled with (for example) a three-parameter exponential function, which is a curve with linear increase and a curved part limited by an asymptote. The curve shape can be represented by a slope with the correct coefficients, which means the vapor generation phenomenon can be modeled correctly using the chosen slope function (within reasonable time limits), which can lead to the actual precursor amount being correlated with the slope coefficients. Additionally or alternatively, other slope functions can be employed for fitting the pressure curve, such as four parameter logistic, and Arrhenius-type formulas.

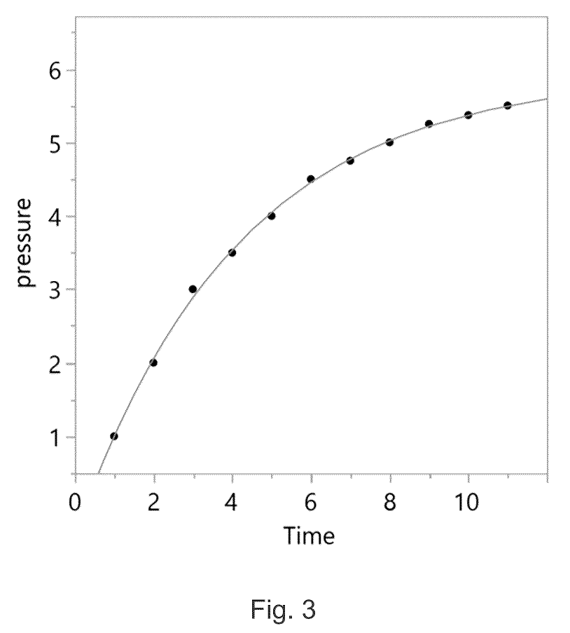

An example of a pressure evolution as a function of time for a full vessel is shown in FIG. 3, in which time is given in seconds and pressure is given in Torr. Pressure as a function of time was fitted using a three-exponent function of the form P(t)=A−Bexp(−Ct), with A being 5.94, B being 6.3, and C being 0.24.

In some embodiments of the pressure disclosure, the pressure gauge is comprised in a precursor line downstream from the precursor vessel and upstream from the reaction chamber. Advantageously though, the pressure gauge is positioned in a precursor vessel. Installing the pressure gauge in the precursor vessel can result in a more accurate measurement, compared to when the precursor vessel is installed in a precursor line.

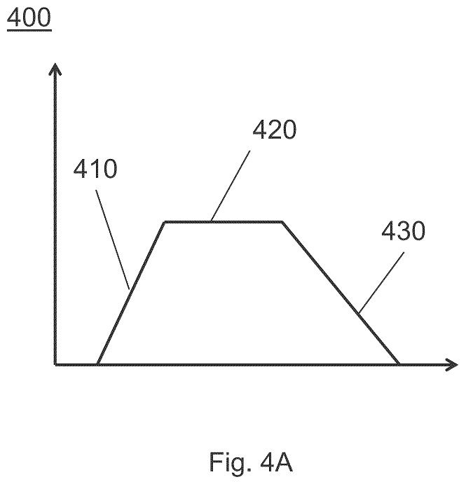

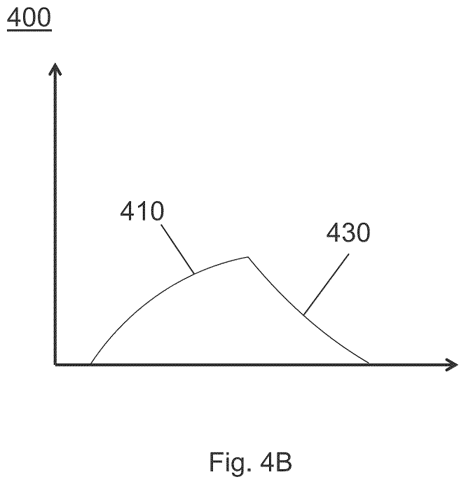

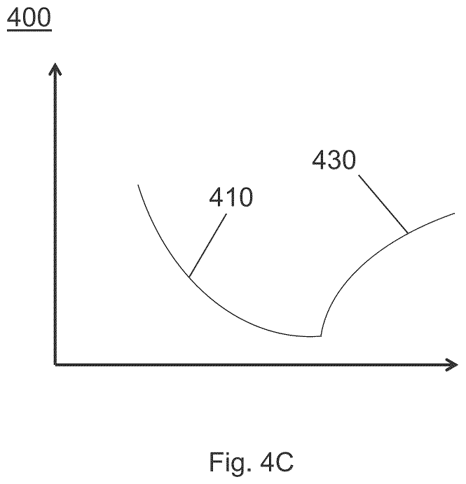

With reference to FIG. 4A, which shows a stylized pressure versus time curve 400 of an embodiment of a precursor pulse, ones from the plurality of pulses comprise at least one of an attack portion 410, a sustain portion 420, and a decay portion 430. Accordingly, the remaining amount of the precursor can be determined by analyzing one or more of the attack portion 410, the sustain portion 420, and the decay portion 430. In some embodiments, and referring to FIG. 4B which shows another embodiment of a stylized pressure versus time curve 400, ones from the plurality of pulses can comprise an attack portion 410 and a decay portion 430.

In some embodiments, the remaining amount of precursor is quantified based on the attack portion 410.

In some embodiments, the attack portion 410 comprises a linear segment, and the remaining amount of the precursor is quantified as being critically low. For example, “critically low” can mean that a precursor vessel is empty or almost empty, for example “almost empty” can mean that the precursor vessel is 20% full or less, or 15% full or less, or 10% full or less, or 5% full or less.

Determining when an attack portion 410 comprises a linear segment, or when it comprises a saturating segment, can be accomplished using statistical methods. For example, saturation or curvedness may be tested by starting with the hypothesis “the attack portion is linear”, which should be an incorrect assumption in case the attack portion comprises a saturating segment, and performing a linear fit on the attack portion. If the R-squared of the linear fit is higher than 0.95 (95%), then we cannot prove ourselves wrong, and we need to accept the conclusion the attack portion comprises a linear segment. If the R-squared is less than 0.95 we cannot say for certain that the line is straight, and the alternative conclusion, i.e. the attack portion comprises a saturating segment, stands.

In some embodiments, the attack portion 410 comprises a saturating segment. In such cases, the remaining amount of the precursor can be quantified as being sufficient. An attack portion 410 comprising a saturating segment is shown in FIGS. 4B and 4C.

In some embodiments, the measured pressure can increase during the attack portion 410, as shown in FIGS. 4A and 4B. This can occur, for example, when the pressure gauge in installed in a precursor line.

In some embodiments, the measured pressure can decrease during the attack portion, as shown in FIG. 4C. This can occur, for example, when the pressure gauge is installed in a precursor vessel.

In some embodiments, the remaining amount of the precursor is determined by analyzing the attack portion. Analyzing the attack portion can comprise fitting the attack portion using a function. The function can, for example, be selected from an exponential function, a four parameter logistic function, and an Arrhenius function.

In some embodiments, the logistic function is a four-parameter function of the form F(x)=D+(A−D)/(1+(x/C)\hat{ }B), in which A, B, C, and D are real numbers, e.g. positive real numbers or negative real numbers.

In some embodiments, the exponential function is a three-parameter exponential function of the form P(t)=A−Bexp(−Ct) in which A, B, and C are real numbers, e.g. positive real numbers or negative real numbers. Such a form can occur when a pressure gauge 225 is installed in a precursor line 220 as shown in FIG. 2B.

In some embodiments, the exponential function is a three-parameter exponential function of the form P(t)=A+Bexp(−Ct) in which A, B, and C are real numbers, e.g. positive real numbers or negative real numbers. Such a form can occur when a pressure gauge 215 is installed in a precursor vessel 210 as shown in FIG. 2A.

In some embodiments, particularly when the sufficient precursor signal is generated, a cyclical deposition process can be executed using the precursor in a reaction chamber which is in fluid connection with the precursor vessel via the precursor line. Thus, the cyclical deposition process can be executed.

In some embodiments, if the insufficient precursor signal is generated, the insufficient precursor signal prevents the system from executing a cyclical deposition process using the precursor in a reaction chamber which is in fluid connection with the precursor vessel via the precursor line.

Providing a pressure-based precursor level measurement according to the present disclosure allows measuring the remaining amount of precursor, and thereby it allows answering the question ‘when do we need to re-fill the vessel’. Nevertheless, any one measurement method is not necessarily foolproof, and a precursor level measurement can be erroneous. Indeed, if one can measure the quantity of material in a precursor vessel, it does not yet guarantee the chemical is intact or will behave as intended. Therefore, it can be useful to add redundancy to the precursor level measurement, and have additional precursor level sensors installed. For example, a capacitive precursor level sensor can be employed in addition to the pressure-based precursor level sensor. Indeed, both sensor types may be used in a system to provide a comprehensive picture of what is happening inside the precursor vessel. The advantage here is we have two types of independent observations, looking at similar things, but based on different phenomena. When the sensor data are aligned, it's indicative of a stable operating regime of the vessel. However, when the data is not in agreement, it provides valuable information about stability, potential sources of instability and improved prediction of break-down of the source. In some embodiments, a precursor level determination based on both capacitive and pressure data can be more accurate than a precursor level determination based on one type of data alone.

Thus, in some embodiments, the precursor vessel further comprises a capacitive sensor that is constructed and arranged for measuring a sensed capacitance. In such embodiments, the analyzing sequence can comprise determining the remaining amount of the precursor based on the sensed capacitance in addition to the pressure as a function of time.

Suitable capacitive sensors are described in U.S. provisional application No. 63/369,695 which is incorporated by reference herein in its entirety.

In some embodiments, the analyzing sequence can comprise determining, based on the sensed capacitance, a capacitance-derived remaining amount of the precursor. Also, a pressure-derived remaining amount of the precursor can be determined based on the pressure as a function of time. The capacitance-derived remaining amount of the precursor and the pressure-derived remaining amount of the precursor can then be compared. These parameters being equal within a pre-determined error range may indicate proper operation. Conversely, these parameters not being equal within the pre-determined error range, can indicate occurrence of an error during precursor level measurement. In some embodiments, the system can be prevented from processing a substrate when the capacitance-derived remaining amount of the precursor and the pressure-derived remaining amount of the precursor are not equal within the pre-determined error range.

Thus, if the capacitance-derived remaining amount of the precursor and the pressure-derived remaining amount of the precursor are equal within a pre-determined margin of error such as 10%, 5%, 2%, 1%, or 0.1%, which can be indicative of a correctly measured remaining amount of the precursor, quantifying the remaining amount of the precursor comprises setting the remaining amount of the precursor equal to the capacitance-derived remaining amount of the precursor, to the pressure-derived remaining amount of the precursor, or to an interpolated value thereof. An interpolated value can, for example, refer to an average, weighted average, or mean value of the pressure-derived remaining amount of the precursor and the capacitance-derived remaining amount of the precursor. Else, i.e. if the capacitance-derived remaining amount of the precursor and the pressure-derived remaining amount of the precursor are not equal within a pre-determined margin of error, an error signal can be generated.

In some embodiments, the pressure measurements and the capacitance measurements are employed for deriving precursor stability. Indeed, a precursor can be determined to be unstable when a capacitive precursor level measurement indicates a substantially higher fill level than a pressure measurement, e.g. when the capacitive derived precursor level is 10%, 20%, 30%, or 40% higher than the pressure-derived precursor level. For example, when a capacitive measurement shows a fill level of 50%, and a pressure measurement shows a fill level of 10%, the precursor can be inferred to have at least partially decomposed, i.e. the precursor can be inferred to be unstable.

In some embodiments, the pressure measurements and the capacitance measurements are employed for deriving fill level and predicted depletion. Indeed, these two different sensing mechanisms can be used in tandem to get a robust estimation of fill level and consumption rate (including loss of precursor via decomposition and similar). If we have an estimation of precursor ‘loss rate’ we can extrapolate and schedule a re-fill (and back-up tool in production) at a reasonably high confidence level.

The subject matter of the present disclosure includes all novel and nonobvious combinations and subcombinations of the various processes, systems, and configurations, and other features, functions, acts, and/or properties disclosed herein, as well as any and all equivalents thereof.

1. A method comprising
providing a plurality of precursor pulses from a precursor vessel to a precursor line in fluid connection with the precursor vessel, the precursor vessel comprising a precursor;
sensing, by a pressure gauge, a pressure as a function of time comprising a plurality of pressure pulses;
carrying out an analyzing sequence, by a processor, of at least the pressure as a function of time, thereby quantifying a remaining amount of the precursor; and
comparing the remaining amount of the precursor to a pre-determined precursor amount, wherein
if the remaining amount of the precursor exceeds the pre-determined precursor amount, generating a sufficient precursor signal; and
if the remaining amount of the precursor is at most equal to the pre-determined precursor amount, generating an insufficient precursor signal.

2. A system comprising
a precursor vessel connector constructed and arranged for operationally connecting to a precursor vessel comprising a precursor;
a reaction chamber being in fluid connection with the precursor vessel via a precursor line; the reaction chamber being constructed and arranged for receiving a plurality of precursor pulses from the precursor vessel via the precursor line;
a pressure gauge being constructed and arranged for sensing a pressure as a function of time, the pressure as a function of time comprising a plurality of pressure pulses; and
a processer constructed and arranged for
carrying out an analyzing sequence that comprises analyzing at least the pressure as a function of time, thereby quantifying a remaining amount of the precursor;
comparing the remaining amount of the precursor to a pre-determined precursor amount; and
comparing the remaining amount of the precursor to a pre-determined precursor amount, wherein
if the remaining amount of the precursor exceeds the pre-determined precursor amount, generating a sufficient precursor signal; and
if the remaining amount of the precursor is at most equal to the pre-determined precursor amount, generating an insufficient precursor signal.

3. The method according to claim 1, wherein the precursor is in a solid state.

4. The method according to claim 1, wherein the precursor comprises a metal center and one or more ligands.

5. The method according to claim 1, wherein each of the plurality of precursor pulses comprise at least one of an attack portion, a sustain portion, and a decay portion, and wherein the remaining amount of the precursor is determined by analyzing one or more of the attack portion, the sustain portion, and the decay portion.

6. The method according to claim 5, wherein the attack portion comprises a linear segment, and wherein the remaining amount of the precursor is quantified as being critically low.

7. The method according to claim 6, wherein the pressure gauge is positioned in the precursor vessel.

8. The method according to claim 5, wherein the attack portion comprises a saturating segment, and wherein the remaining amount of the precursor is quantified as being sufficient.

9. The method according to claim 1, wherein, if the sufficient precursor signal is generated, a cyclical deposition process is executed using the precursor in a reaction chamber which is in fluid connection with the precursor vessel via the precursor line.

10. The method according to claim 1, wherein, if the insufficient precursor signal is generated, the insufficient precursor signal prevents execution of a cyclical deposition process using the precursor in a reaction chamber which is in fluid connection with the precursor vessel via the precursor line.

11. The method according to claim 5, wherein the remaining amount of the precursor is determined by analyzing the attack portion, and wherein analyzing the attack portion comprises fitting the attack portion using a function selected from an exponential function, a four-parameter logistic function, and an Arrhenius function.

12. The method according to claim 11, wherein the exponential function is a three-parameter exponential function of a form P(t)=A−Bexp(−Ct) in which A, B, and C are positive real numbers.

13. The method according to claim 1, wherein the precursor vessel further comprises a capacitive sensor that is constructed and arranged for measuring a sensed capacitance, and wherein the analyzing sequence comprises determining the remaining amount of the precursor based on the sensed capacitance in addition to the pressure as a function of time.

14. The method according to claim 13, wherein the analyzing sequence comprises:
determining, based on the sensed capacitance, a capacitance-derived remaining amount of the precursor;
determining, based on the pressure as a function of time, a pressure-derived remaining amount of the precursor;
comparing the capacitance-derived remaining amount of the precursor and the pressure-derived remaining amount of the precursor, wherein
if the capacitance-derived remaining amount of the precursor and the pressure-derived remaining amount of the precursor are equal within a pre-determined margin of error, quantifying the remaining amount of the precursor comprises setting the remaining amount of the precursor equal to the capacitance-derived remaining amount of the precursor, to the pressure-derived remaining amount of the precursor, or to an interpolated value thereof; and
if the capacitance-derived remaining amount of the precursor and the pressure-derived remaining amount of the precursor are equal within a pre-determined margin of error, generating an error signal.

15. A precursor vessel comprising:
a precursor;
a pressure gauge; and
a capacitive sensor,
the precursor vessel being fluidly connectable to a reaction chamber via a precursor line, the reaction chamber and the precursor line being comprised in a vapor deposition system, the reaction chamber being constructed and arranged for receiving a plurality of precursor pulses from the precursor vessel via the precursor line;
the pressure gauge being constructed and arranged for sensing a pressure as a function of time, the pressure as a function of time comprising a plurality of pressure pulses;
the capacitive sensor being constructed and arranged for measuring a sensed capacitance; and
the precursor vessel being operationally connectable to a processer comprised in the vapor deposition system, the processer being constructed and arranged for
carrying out an analyzing sequence that comprises analyzing one or both of the pressure as a function of time and the sensed capacitance, thereby quantifying a remaining amount of the precursor; and
comparing the remaining amount of the precursor to a pre-determined precursor amount, wherein
if the remaining amount of the precursor exceeds the pre-determined precursor amount, generating a sufficient precursor signal; and
if the remaining amount of the precursor is at most equal to the pre-determined precursor amount, generating an insufficient precursor signal.

16. The precursor vessel according to claim 15, wherein the precursor is a solid precursor.

17. The precursor vessel according to claim 15, wherein the precursor comprises a center and one or more ligands, wherein the center is selected from a transition metal, a post transition metal, a lanthanide, and a metalloid; and wherein the one or more ligands are independently selected from a list consisting of arene, halide, alkyl, cyclopentadienyl, amide, chelating nitrogen-containing ligand, alkoxide, beta-diketonate, and carbonyl.

18. A data processing unit comprising:
a receiving unit constructed and arranged for receiving a pressure as a function of time, the pressure as a function of time comprising a plurality of pressure pulses;
an analyzing unit constructed and arranged for carrying out an analyzing sequence of at least the pressure as a function of time, thereby quantifying a remaining amount of a precursor;
a comparison unit constructed and arranged for comparing the remaining amount of the precursor to a pre-determined precursor amount; and
a generating unit, the generating unit constructed and arranged for
generating a sufficient precursor signal if the remaining amount of the precursor exceeds the pre-determined precursor amount; and
generating an insufficient precursor signal if the remaining amount of the precursor is at most equal to the pre-determined precursor amount.

19. A non-transitory computer-readable medium having stored thereon instructions, which when executed by a processing unit, execute the method according to claim 1.
